(19) United States
(12) Patent Application Publication
(10) Pub. No.: US 2025/0311308 A1
(43) Pub. Date: Oct. 2, 2025

(54) THIN FILM TRANSISTOR AND METHOD OF MANUFACTURING THIN FILM TRANSISTOR

(71) Applicants: Beijing Superstring Academy of Memory Technology, Beijing (CN); INSTITUTE OF MICROELECTRONICS, CHINESE ACADEMY OF SCIENCES, Beijing (CN)

(72) Inventors: Gaobo XU, Beijing (CN); Yanyu YANG, Beijing (CN); Gangping YAN, Beijing (CN); Chuqiao NIU, Beijing (CN); Jie LUO, Beijing (CN)

(73) Assignees: Beijing Superstring Academy of Memory Technology, Beijing (CN); INSTITUTE OF MICROELECTRONICS, CHINESE ACADEMY OF SCIENCES, Beijing (CN)

(21) Appl. No.: 18/988,124

(22) Filed: Dec. 19, 2024

(30) Foreign Application Priority Data
Mar. 27, 2024 (CN) 202410362413.8

(51) Int. Cl. H10D 30/67; H01L 21/02; H10D 30/01; H10D 62/10; H10D 64/27

(52) U.S. Cl. CPC H10D 30/6757; H01L 21/02664; H10D 30/0318; H10D 30/6704; H10D 30/6728; H10D 62/116; H01L 21/02266; H10D 64/518

(57) ABSTRACT

The present disclosure provides a thin film transistor and a method of manufacturing a thin film transistor. The thin film transistor includes a first conductive layer, an isolation layer and a semiconductor layer. The isolation layer is formed on a side of the first conductive layer, the isolation layer includes a body portion and a buffer portion that are arranged continuously, the body portion includes a first surface away from and in parallel to the first conductive layer, and a thickness of the buffer portion gradually decreases from a side close to the body portion to a side away from the body portion. The semiconductor layer includes a first portion and a second portion that are arranged continuously, the first portion is formed on a side of the isolation layer away from the first conductive layer, and the second portion is in contact with the first conductive layer.

### CROSS REFERENCE TO RELATED APPLICATION

This application claims priority to Chinese Patent Application No. 202410362413.8, filed on Mar. 27, 2024, the entire content of which is incorporated herein in its entirety by reference.

### TECHNICAL FIELD

The present disclosure relates to a field of semiconductor technology, and in particular to a thin film transistor and a method of manufacturing a thin film transistor.

### BACKGROUND

Amorphous oxide-semiconductor thin film transistor (OSTFT) has great prospects in fields of display and storage due to its low leakage current and simple low-temperature manufacturing process.

At present, structures of thin film transistor devices mainly include a planar structure and a vertical channel structure. A planar structure device has a mature process but occupies a large area. A vertical channel device occupies a small area but have a low product yield because it is difficult to deposit a channel layer on a vertical sidewall. Therefore, it is difficult for a thin film transistor device in the related art to achieve a balance between an occupied area and a manufacturing yield.

### SUMMARY

In a first aspect of the present disclosure, a thin film transistor is provided, including:
a first conductive layer;
an isolation layer formed on a side of the first conductive layer, where the isolation layer includes a body portion and a buffer portion that are arranged continuously, the body portion includes a first surface away from the first conductive layer, the first surface is parallel to the first conductive layer, and a thickness of the buffer portion gradually decreases from a side close to the body portion to a side away from the body portion; and
a semiconductor layer, where the semiconductor layer includes a first portion and a second portion that are arranged continuously, the first portion is formed on a side of the isolation layer away from the first conductive layer, and the second portion is in contact with the first conductive layer.

In a second aspect of the present disclosure, a method of manufacturing a thin film transistor is provided, including:
forming a first conductive layer;
forming an isolation layer on a side of the first conductive layer, where the isolation layer includes a body portion and a buffer portion that are arranged continuously, the body portion includes a first surface away from the first conductive layer, the first surface is parallel to the first conductive layer, and a thickness of the buffer portion gradually decreases from a side close to the body portion to a side away from the body portion; and
forming a semiconductor layer, where the semiconductor layer includes a first portion and a second portion that are arranged continuously, the first portion is formed on a side of the isolation layer away from the first conductive layer, and the second portion is in contact with the first conductive layer.

### BRIEF DESCRIPTION OF THE DRAWINGS

Various additional advantages and benefits will become apparent to those ordinary skilled in the art from a reading of the following detailed description of the preferred embodiments. The accompanying drawings are only for the purpose of illustrating the preferred embodiments and should not be considered limiting of the present disclosure. Also, throughout the accompanying drawings, the same reference numerals are used to represent the same components. In the accompanying drawings:

FIG. 1 shows a schematic structural diagram of a thin film transistor provided in an embodiment of the present disclosure.

FIG. 2 shows a top view of an isolation layer in a thin film transistor provided in an embodiment of the present disclosure.

FIG. 3 shows a top view of a second conductive layer in a thin film transistor provided in an embodiment of the present disclosure.

FIG. 4 shows a top view of a second conductive layer in another thin film transistor provided in an embodiment of the present disclosure.

FIG. 5 shows a schematic structural diagram of a thin film transistor provided in an embodiment of the present disclosure.

FIG. 6 shows a schematic structural diagram of a thin film transistor provided in an embodiment of the present disclosure.

FIG. 7 shows a flowchart of a method of manufacturing a thin film transistor provided in an embodiment of the present disclosure.

FIG. 8 to FIG. 12 show schematic diagrams of film layer changes during a manufacturing process of a thin film transistor provided in an embodiment of the present disclosure.

The reference numerals are as follows.

1 represents a thin film transistor; 11 represents a substrate; 12 represents a first conductive layer; 13 represents an isolation layer; 131 represents a body portion; 132 represents a buffer portion; 1311 represents a first surface; 14 represents a semiconductor layer; 141 represents a first portion; 142 represents a second portion; 15 represents a second conductive layer; 151 represents a first through hole; 16 represents a third conductive layer; 17 represents a first insulating layer; 171 represents a second through hole; 18 represents a second insulating layer; 181 represents a third through hole; C1 represents a first modified region; NC represents a first non-modified region; C2 represents a second modified region; 19 represents a fourth conductive layer; and 20 represents a substrate isolation layer.

### DETAILED DESCRIPTION OF EMBODIMENTS

Exemplary embodiments of the present disclosure will be described below in more detail with reference to the accompanying drawings. Although the exemplary embodiments of the present disclosure are shown in the accompanying drawings, it should be understood that the present disclosure may be implemented in various forms and should not be limited to the embodiments set forth herein. On the contrary, these embodiments are provided to enable a more thorough understanding of the present disclosure and to fully convey the scope of the present disclosure to those skilled in the art.

It should be understood that the terms used herein are for the purpose of describing particular example embodiments only and are not intended to be limiting. As used herein, the singular forms “a”, “an” and “the” may also be intended to include the plural forms, unless the context clearly indicates otherwise. The terms “comprising”, “including”, “containing” and “having” are inclusive, and thus specify the presence of stated features, steps, operations, elements and/or components, but do not exclude the presence or addition of one or more other features, steps, operations, elements, components and/or combinations thereof. The method steps, processes and operations described herein are not to be construed as necessarily being required to be executed in the particular order described or illustrated, unless an order of execution is explicitly stated. It should also be understood that additional or alternative steps may be used.

Although the terms “first”, “second”, “third”, etc. may be used herein to describe various elements, components, regions, layers and/or sections, these elements, components, regions, layers and/or sections should not be limited by these terms. These terms may be only used to distinguish one element, component, region, layer or section from another one. The terms such as “first”, “second” and other numerical terms when used herein do not imply a sequence or order unless clearly indicated by the context. Therefore, a first element, a first component, a first region, a first layer or a first section discussed below may also be referred to as a second element, a second component, a second region, a second layer or a second section without departing from the teachings of example embodiments.

For ease of description, spatial relative terms may be used herein to describe a relationship of one element or feature relative to another element or feature as shown in the figures. These relative terms may include, for example, “internal”, “external”, “inside”, “outside”, “under”, “below”, “on”, “above”, etc. The spatial relative terms are intended to include different orientations of a device in use or operation in addition to the orientations depicted in the figures. For example, if a device in the figures is turned over, an element described as “under” or “below” other elements or features may then be oriented “on” or “above” the other elements or features. Thus, the example term “below” may include both an orientation of above and below. The device may be otherwise oriented (rotated 90 degrees or at other orientations) and the spatial relative description used herein should be interpreted accordingly.

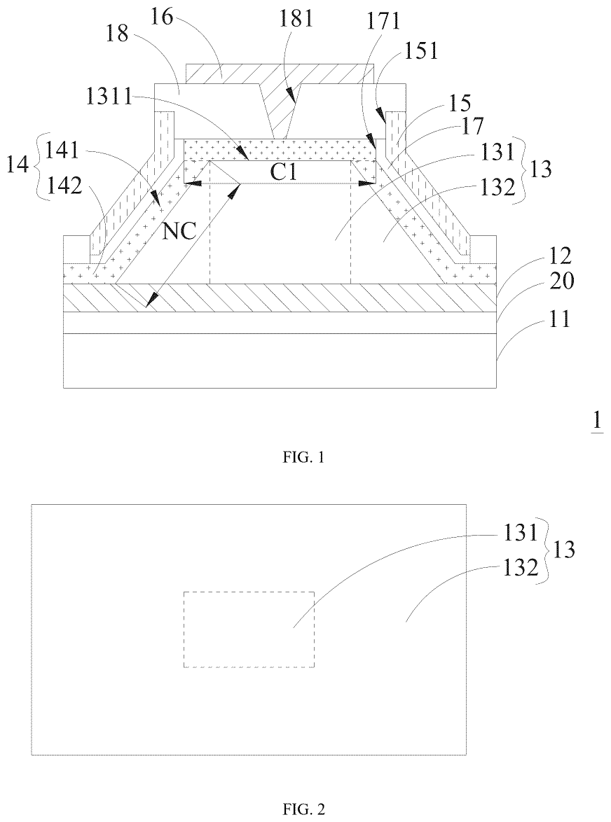

As shown in FIG. 1, according to an embodiment of the present disclosure, a thin film transistor 1 is provided, including a first conductive layer 12, an isolation layer 13 and a semiconductor layer 14. The isolation layer 13 is formed on a side of the first conductive layer 12. The isolation layer 13 includes a body portion 131 and a buffer portion 132 that are arranged continuously. The body portion 131 includes a first surface 1311 away from the first conductive layer 12, and the first surface 1311 is parallel to the first conductive layer 12. A thickness of the buffer portion 132 gradually decreases from a side close to the body portion 131 to a side away from the body portion 131. The semiconductor layer 14 includes a first portion 141 and a second portion 142 that are arranged continuously. The first portion 141 is formed on a side of the isolation layer 13 away from the first conductive layer 12, and the second portion 142 is in contact with the first conductive layer 12.

The thin film transistor 1 provided in the present disclosure includes the first conductive layer 12, the isolation layer 13 and the semiconductor layer 14. The first conductive layer 12 may be used to form a first electrode of the thin film transistor 1. The semiconductor layer 14 is used to form a source region, a drain region and a channel region of the thin film transistor 1. The isolation layer 13 is formed on a side of the first conductive layer 12 and is used to space the semiconductor layer 14, so as to reduce an area of the thin film transistor 1 in a case of a fixed channel length in the semiconductor layer 14. A surface of the isolation layer 13 on a side away from the first conductive layer 12 includes a body portion 131 and a buffer portion 132 that are arranged continuously. The body portion 131 includes a first surface 1311 on a side away from the first conductive layer 12, and the first surface 1311 is parallel to the first conductive layer 12. A thickness of the buffer portion 132 gradually decreases from a side close to the body portion 131 to a side away from the body portion 131, so that the surface of the isolation layer 13 on the side away from the first conductive layer 12 may achieve a slow transition. The semiconductor layer 14 includes a first portion 141 and a second portion 142 that are arranged continuously. The first portion 141 is formed on a side of the isolation layer 13 away from the first conductive layer 12, and the second portion 142 is in contact with the first conductive layer 12 to achieve a connection between the first electrode and the source region or the drain region in the semiconductor layer 14. Due to the existence of the buffer portion 132, the surface of the isolation layer 13 on the side away from the first conductive layer 12 may achieve a slow transition, so that the first portion 141 of the semiconductor layer 14 located on the side of the isolation layer 13 away from the first conductive layer 12 has a good uniformity of film thickness, thereby improving a negative drift of threshold voltage caused by an increase of oxygen vacancy concentration due to a too large film thickness of the semiconductor layer 14, and improving a channel disconnection and a source-drain disconnection due to a too small thickness of some regions in the semiconductor layer 14, which helps to improve the manufacturing yield of the semiconductor layer 14, improve the stability of the thin film transistor 1, and take into account the area of the thin film transistor 1, thereby improving the integration.

In the above embodiments, the transistor may further include a substrate 11, which may be made of silicon. The substrate 11 may include a plane. The first conductive layer 12 may be formed on a side of the substrate 11 and include a plane on a side away from the substrate.

In the above embodiments, a cross section of the buffer portion 132 parallel to a thickness direction of the buffer portion 132 may be a triangle, that is, a surface of the buffer portion 132 on a side away from the first conductive layer 12 is an inclined surface, or the surface of the buffer portion 132 on the side away from the first conductive layer 12 is a curved surface (not shown), both of which may improve the uniformity of the film thickness of the first portion 141 at a junction of the body portion 131 and the buffer portion 132 as well as on the surface of the buffer portion 132.

When the cross section of the buffer portion 132 parallel to the thickness direction of the buffer portion 132 is a triangle, a cross section of the isolation layer 13 parallel to a thickness direction of the isolation layer 13 may be a trapezoid. Both bottom angles of the trapezoid close to the first conductive layer 12 are acute angles, which may be greater than or equal to 45° and less than 90°.

When the surface of the buffer portion 132 on the side away from the first conductive layer 12 is a curved surface, the curved surface may be a curved surface convex toward an inner side of the isolation layer 13 or a curved surface protruding away from the inner side of the isolation layer 13, which is not particularly limited in the present disclosure.

Alternatively, the surface of the buffer portion 132 on the side away from the first conductive layer 12 may be an inclined surface, and the first surface 1311 is transitioned to the inclined surface through a chamfer, so as to improve the uniformity of the film thickness of the semiconductor layer 14 and thus improve the manufacturing yield.

In the above embodiments, the first conductive layer 12 may be made of TiN, TaN, etc., and the semiconductor layer 14 may be made of In₂O₃, ZnO or IGZO, etc.

The thin film transistor 1 provided in the present disclosure may further include a substrate isolation layer 20, which is formed between the substrate 11 and the first conductive layer 12. The substrate isolation layer 20 may be made of SiO₂, Si₃N₄, etc.

In a feasible embodiment, as shown in FIG. 2, the buffer portion 132 surrounds at least a part of the body portion 131 along a circumferential direction of the body portion 131.

Specifically, the buffer portion 132 may be formed on a side of the body portion 131, and the body portion 131 and the buffer portion 132 are arranged in a direction parallel to a plane where the first conductive layer 12 is located. Alternatively, the buffer portion 132 surrounds the body portion 131 along the circumferential direction of the body portion 131.

In a feasible embodiment, as shown in FIG. 1, the thin film transistor 1 further includes a second conductive layer 15 and a third conductive layer 16. The second conductive layer 15 is formed on a side of the semiconductor layer 14 away from the first conductive layer 12, and the second conductive layer 15 includes a first through hole 151 that exposes at least a part of the first portion 141. The second conductive layer 15 is insulated from the first conductive layer 12. The third conductive layer 16 is formed on a side of the first portion 141 of the semiconductor layer 14 away from the isolation layer 13 and is in contact with the first portion 141 of the semiconductor layer 14. The third conductive layer 16 is insulated from the second conductive layer 15.

In the above embodiments, the second conductive layer 15 is used to form a control electrode of the thin film transistor 1, and the third conductive layer 16 is used to form a second electrode of the thin film transistor 1. The second conductive layer 15 is insulated from the third conductive layer 16, and the second conductive layer 15 is insulated from the first conductive layer 12.

Specifically, the first electrode may be one of a source electrode and a drain electrode, the second electrode may be the other of the source electrode and the drain electrode, and the control electrode may be a gate electrode.

In the above embodiments, as shown in FIG. 1, the second conductive layer 15 is formed on a side of the semiconductor layer 14 away from the first conductive layer 12. The second conductive layer 15 includes a first through hole 151 that exposes at least a part of the first portion 141, so as to facilitate a subsequent contact connection between the third conductive layer 16 and the first portion 141. Specifically, a part of the first portion 141 in contact with the first surface 1311 may be exposed. The third conductive layer 16 is formed on a side of the first portion 141 of the semiconductor layer 14 away from the isolation layer 13 and extends at least partially into the first through hole 151 to achieve a contact connection with the first portion 141.

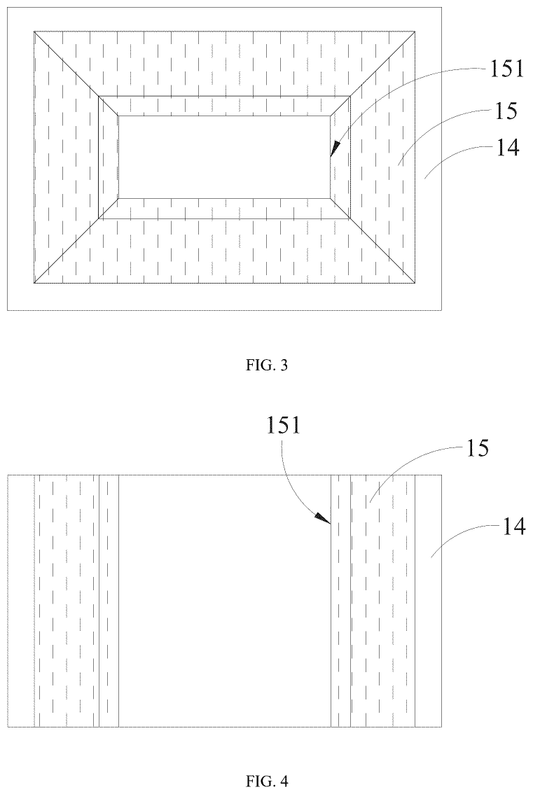

In the above embodiments, the second conductive layer 15 may surround at least a part of the body portion 131 along the circumferential direction of the body portion 131. Specifically, as shown in FIG. 3, the second conductive layer 15 may surround one circumference of the body portion 131; or as shown in FIG. 4, the second conductive layer 15 may be separated into two parts by the first through hole 151, and the two parts are provided on both sides of the body portion 131 respectively.

In the above embodiments, it is also possible to adjust a distance that the second conductive layer 15 climbs along the buffer portion 132 by adjusting a thickness of the isolation layer 13 and a decreasing speed of the thickness of the buffer portion 132, thereby adjusting a length of the control electrode. In a case of fixed material and width of the control electrode, the smaller the length of the control electrode, the larger the on-state current, and the better the performance. By adjusting the length of the control electrode using the above process, it is not required to adjust the length of the control electrode by using a photolithography process, so that a process difficulty may be reduced.

Specifically, the thickness of the isolation layer 13 may be in a range of 100 nanometers to 300 nanometers, and the length of the control electrode may be less than 50 nanometers.

In a feasible embodiment, as shown in FIG. 1, the thin film transistor 1 further includes a first insulating layer 17 and a second insulating layer 18. The first insulating layer 17 is formed on a side of the semiconductor layer 14 away from the first conductive layer 12. The first insulating layer 17 includes a second through hole 171, and an orthographic projection of the second through hole 171 on the first conductive layer 12 overlaps at least partially with an orthographic projection of the first through hole 151 on the first conductive layer 12. The second insulating layer 18 is formed on a side of the first portion 141 away from the first conductive layer 12, and the second insulating layer 18 covers an edge of the first through hole 151 and an edge of the second through hole 171. The second insulating layer 18 includes a third through hole 181 that exposes a part of the first portion 141. The third conductive layer 16 extends at least partially into the third through hole 181 and is in contact with the first portion 141.

In the above embodiments, the first insulating layer 17 is formed on a side of the semiconductor layer 14 away from the first conductive layer 12, so as to insulate the semiconductor layer 14 from the second conductive layer 15. The first insulating layer 17 includes a second through hole 171. The orthographic projection of the second through hole 171 on the first conductive layer 12 overlaps at least partially with the orthographic projection of the first through hole 151 on the first conductive layer 12, so that the third conductive layer 16 may extend into the first through hole 151 and the second through hole 171 and may be in contact with the semiconductor layer 14.

In the above embodiments, the second insulating layer 18 is formed on the side of the first portion 141 away from the first conductive layer 12, so as to insulate the second conductive layer 15 from the third conductive layer 16 and to protect the semiconductor layer 14. The second insulating layer 18 covers the edge of the first through hole 151 and the edge of the second through hole 171 to prevent the third conductive layer 16 from contacting the second conductive layer 15, thereby insulating the two. The second insulating layer 18 includes a third through hole 181 that exposes a part of the first portion 141, so that the third conductive layer 16 extends at least partially into the third through hole 181 and is in contact with the first portion 141.

In the above embodiments, the first insulating layer 17 may be made of Al₂O₃, HfO₂ or SiO₂, etc., and the second insulating layer 18 may be made of Al₂O₃, HfO₂ or SiO₂, etc., which are not particularly limited in the present disclosure.

In a feasible embodiment, as shown in FIG. 1, the first portion 141 includes a first modified region C1 and a first non-modified region NC, and the first modified region C1 is located on the first surface 1311. The first modified region C1 has a greater carrier concentration than the first non-modified region NC, and the first modified region C1 is in contact with the third conductive layer 16.

In the above embodiments, it is possible to perform a modification treatment on the semiconductor layer 14, so that the first portion 141 may include the first modified region C1 and the first non-modified region NC. The first modified region C1 has a greater carrier concentration than the first non-modified region NC, and the third conductive layer 16 is in contact with the first modified region C1, thereby reducing a contact resistance between the third conductive layer 16 and the semiconductor layer 14. The modification treatment includes plasma bombardment or ion implantation.

Specifically, the first modified region C1 has more oxygen vacancies and may provide more carriers, so that the contact resistance may be reduced and the performance of the thin film transistor 1 may be further improved.

In the above embodiments, the modification treatment may be performed on the semiconductor layer 14 after the formation of the second conductive layer 15 and before the formation of the third conductive layer 16. The second conductive layer 15 includes a first through hole 151. The first through hole 151 exposes a part of the first portion 141 or the entire first portion 141, and specifically may expose a part of the first portion 141 that is opposite to the first surface in a direction perpendicular to the first conductive layer 12. The modification treatment on the semiconductor layer 14 may be performed only on a region of the semiconductor layer 14 exposed by the first through hole 151.

In the above embodiments, a device used to perform the modification treatment on the semiconductor layer 14 is located on a side of the semiconductor layer 14 away from the first conductive layer 12, so that a good modification effect may be achieved on the surface of the semiconductor layer 14 on the side away from the first conductive layer 12. The modification treatment is performed on the semiconductor layer 14 first, and then the third conductive layer 16 is formed, so that a good modification effect is achieved on the surface of the semiconductor layer 14 in contact with the third conductive layer 16, thereby improving a resistance reduction effect. Furthermore, only the surface of the semiconductor layer 14 in contact with the third conductive layer 16 is modified, so that an adverse effect on the manufacturing yield of the semiconductor layer 14 may be reduced.

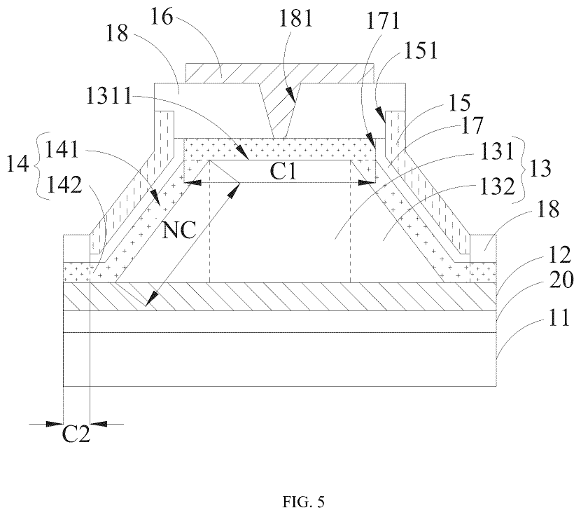

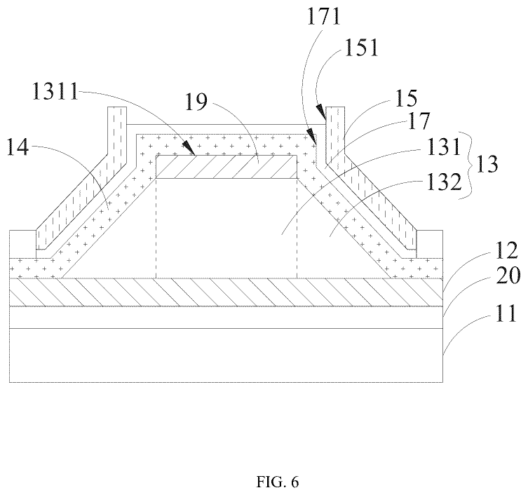

In a feasible embodiment, as shown in FIG. 5, the second portion 142 includes a second modified region C2 in contact with the first conductive layer 12. The second modified region C2 has a greater carrier concentration than the first non-modified region NC.

In the above embodiments, the second portion 142 may include a region not covered by the second conductive layer 15. Such region of the second portion 142 is in contact with the first conductive layer 12 and may be modified to form a second modified region C2. The second modified region C2 may be manufactured by the same process as the first modified region C1. The second modified region C2 has a great carrier concentration, and the second modified region C2 is in contact with the first conductive layer 12, so that a contact resistance between the second modified region C2 and the first conductive layer 12 may be reduced.

Specifically, the carrier concentration of the first modified region C1 may be 3 to 4 times that of the first non-modified region NC, and the carrier concentration of the second modified region C2 may be 3 to 4 times that of the first non-modified region NC. The carrier concentration of the second modified region C2 may be the same as that of the first modified region C1.

In a feasible embodiment, as shown in FIG. 5, the thin film transistor 1 further includes a second conductive layer 15 and a fourth conductive layer 19. The second conductive layer 15 is formed on a side of the semiconductor layer 14 away from the first conductive layer 12, and the second conductive layer 15 is insulated from the first conductive layer 12. The fourth conductive layer 19 is formed between the first surface 1311 of the body portion 131 and the first portion 141, and the fourth conductive layer 19 is in contact with the first portion 141 and the first surface 1311 of the body portion 131.

In the above embodiments, the second conductive layer 15 is used to form the control electrode of the thin film transistor 1, and the fourth conductive layer 19 is used to form the second electrode of the thin film transistor 1. The second conductive layer 15 is insulated from the fourth conductive layer 19, and the second conductive layer 15 is insulated from the first conductive layer 12.

Specifically, the first electrode may be one of a source electrode and a drain electrode, the second electrode may be the other of the source electrode and the drain electrode, and the control electrode may be a gate electrode.

In the above embodiments, the fourth conductive layer 19 is provided between the semiconductor layer 14 and the isolation layer 13, and the fourth conductive layer 19 is separated from the second conductive layer 15 through the semiconductor layer 14, so that the second insulating layer 18 may be omitted, which helps to reduce a thickness of the thin film transistor 1.

Specifically, the thin film transistor 1 includes a third conductive layer 16 or a fourth conductive layer 19.

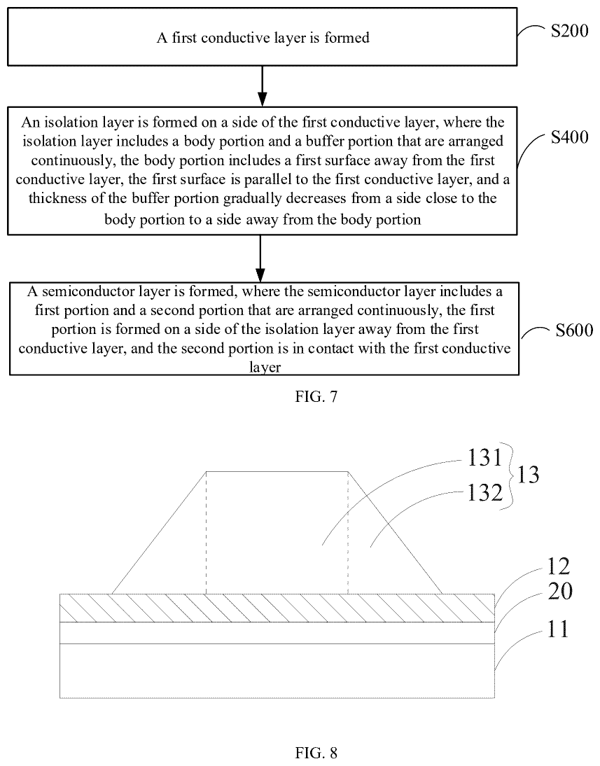

The present disclosure further provides a method of manufacturing a thin film transistor, including the following steps S200 to S600, as shown in FIG. 7.

In S200, as shown in FIG. 8, a first conductive layer 12 is formed.

Specifically, the first conductive layer 12 may be formed by a deposition process.

In S400, as shown in FIG. 8, an isolation layer 13 is formed on a side of the first conductive layer 12, where the isolation layer 13 includes a body portion 131 and a buffer portion 132 that are arranged continuously, the body portion 131 includes a first surface 1311 away from the first conductive layer 12, the first surface 1311 is parallel to the first conductive layer 12, and a thickness of the buffer portion 132 gradually decreases from a side close to the body portion 131 to a side away from the body portion 131.

Specifically, the body portion 131 and the buffer portion 132 may be integrally formed. It is possible to first form an isolation material layer by a deposition process and then pattern the isolation material layer to form the body portion 131 and the buffer portion 132.

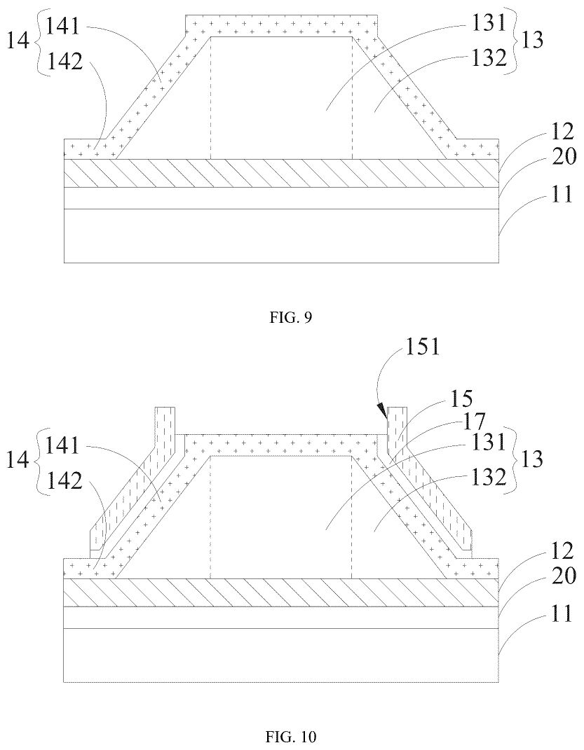

In S600, as shown in FIG. 9, a semiconductor layer 14 is formed, where the semiconductor layer 14 includes a first portion 141 and a second portion 142 that are arranged continuously, the first portion 141 is formed on a side of the isolation layer 13 away from the first conductive layer 12, and the second portion 142 is in contact with the first conductive layer 12.

In the manufacturing method provided in the present disclosure, an isolation structure layer is patterned to form an isolation layer 13, and the isolation layer 13 includes a body portion 131 and a buffer portion 132. The body portion 131 includes a first surface 1311 on a side away from the first conductive layer 12, and the first surface 1311 is parallel to a plane where the first conductive layer 12 is located. A thickness of the buffer portion 132 gradually decreases from a side close to the body portion 131 to a side away from the body portion 131, so that the isolation layer 13 formed has a smooth surface. When proceeding to form the semiconductor layer 14, the semiconductor layer 14 is formed on the surface of the isolation layer 13 on the side away from the first conductive layer 12 through a deposition process, and a shape of the semiconductor layer 14 is similar to that of the surface of the isolation layer 13 on the side away from the first conductive layer 12, so that the uniformity of the film thickness of the semiconductor layer 14 may be improved and a risk of breakage and failure may be reduced.

Specifically, before step S200, the method may further include step S100 of providing a substrate 11 and forming a substrate isolation layer 20 on a side of the substrate. Then step S200 is performed to form the first conductive layer 12 on a side of the substrate isolation layer 20 away from the substrate 11. The substrate isolation layer 20 is used to isolate and protect the substrate 11 and the first conductive layer 12.

In a feasible embodiment, the manufacturing method further includes the following steps S800 and S1000.

In S800, as shown in FIG. 10, a second conductive layer 15 is formed on a side of the semiconductor layer 14 away from the first conductive layer 12, and a first through hole 151 is formed in the second conductive layer 15. The first through hole 151 exposes at least a part of the first portion 141, and the second conductive layer 15 is insulated from the first conductive layer 12.

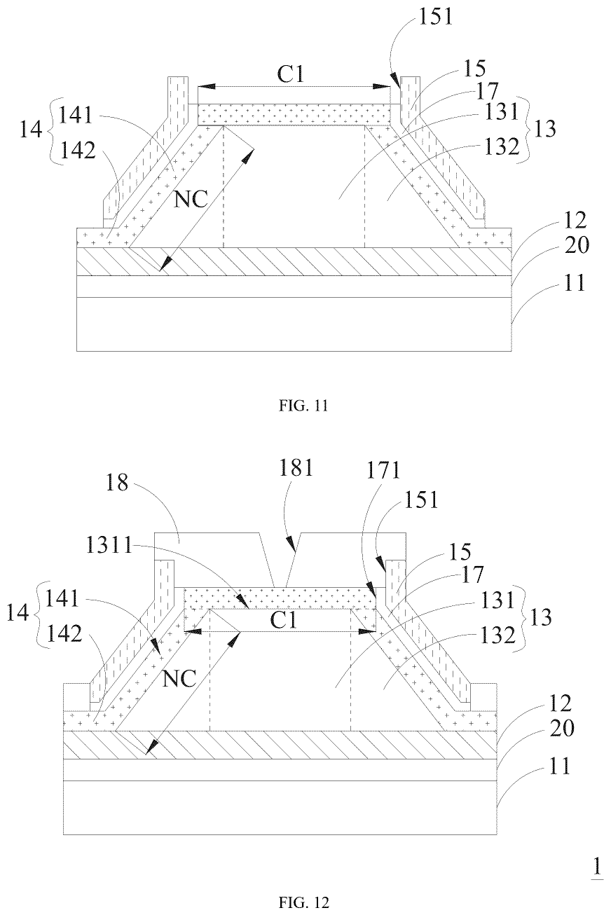

In S1000, as shown in FIG. 11, a first modified region C1 and a first non-modified region NC are formed in the first portion 141, where the first modified region C1 is formed by performing a modification treatment on the part of the first surface 1311 exposed by the first through hole 151. The modification treatment includes plasma bombardment or ion implantation, and the first modified region C1 has a greater carrier concentration than the first non-modified region NC.

In the above embodiments, the modification treatment may be performed on the semiconductor layer 14 after the formation of the second conductive layer 15 and before the formation of the third conductive layer 16. The second conductive layer 15 includes a first through hole 151. The first through hole 151 exposes a part of the first portion 141 or the entire first portion 141. The modification treatment on the semiconductor layer 14 may be performed only on a region of the semiconductor layer 14 exposed by the first through hole 151.

In the above embodiments, a device used to perform the modification treatment on the semiconductor layer 14 is located on a side of the semiconductor layer 14 away from the first conductive layer 12, so that a good modification effect may be achieved on the surface of the semiconductor layer 14 on the side away from the first conductive layer 12. The modification treatment is performed on the semiconductor layer 14 first, and then the third conductive layer 16 is formed, so that a good modification effect is achieved on the surface of the semiconductor layer 14 in contact with the third conductive layer 16, thereby improving a resistance reduction effect. Furthermore, only the surface of the semiconductor layer 14 in contact with the third conductive layer 16 is modified, so that an adverse effect on the manufacturing yield of the semiconductor layer 14 may be reduced. Performing the modification treatment only on the surface of the semiconductor layer 14 may avoid over-treatment of the semiconductor layer 14 during the modification treatment and thus avoid affecting the performance of the semiconductor layer 14.

In the above embodiments, the modification treatment includes plasma bombardment or ion implantation, etc., and may further include other treatment methods, which are not particularly limited in the present disclosure.

The above-mentioned modification treatment is simple and mature, and has a significant effect on improving the performance of the thin film transistor 1.

In a feasible embodiment, the manufacturing method further includes the following steps S800 and S1200.

In S800, a second conductive layer 15 is formed on a side of the semiconductor layer 14 away from the first conductive layer 12, and a first through hole 151 is formed in the second conductive layer 15. The first through hole 151 exposes at least a part of the first portion 141, and the second conductive layer 15 is insulated from the first conductive layer 12.

In S1200, as shown in FIG. 12, a second insulating layer 18 is formed on a side of the first portion 141 away from the first conductive layer 12 by a magnetron sputtering process. The second insulating layer 18 covers an edge of the first through hole 151, and the second insulating layer 18 includes a third through hole 181 that exposes a part of the first portion 141.

When the thin film transistor 1 includes the second conductive layer 15 and the third conductive layer 16, it may further include a second insulating layer 18 for insulating the second conductive layer 15 from the third conductive layer 16. The second insulating layer 18 may be further used to protect the semiconductor layer 14. The second insulating layer 18 may be formed by chemical vapor deposition or magnetron sputtering. When the second insulating layer 18 is formed on the side of the first portion 141 away from the first conductive layer 12 by magnetron sputtering, a modification treatment may be performed on the semiconductor layer 14 simultaneously, so that a specific modification treatment on the semiconductor layer 14 may be omitted, thereby simplifying the manufacturing process and reducing the manufacturing cost.

The above are merely preferred specific embodiments of the present disclosure, and the scope of protection of the present disclosure is not limited thereto. Any changes or substitutions that may be easily conceived by those skilled in the art within the technical scope disclosed in the present disclosure fall within the scope of protection of the present disclosure. Therefore, the scope of protection of the present disclosure should be defined by the appended claims.

What is claimed is:

1. A thin film transistor, comprising:
a first conductive layer;
an isolation layer formed on a side of the first conductive layer, wherein the isolation layer comprises a body portion and a buffer portion that are arranged continuously, the body portion comprises a first surface away from the first conductive layer, the first surface is parallel to the first conductive layer, and a thickness of the buffer portion gradually decreases from a side close to the body portion to a side away from the body portion; and
a semiconductor layer, wherein the semiconductor layer comprises a first portion and a second portion that are arranged continuously, the first portion is formed on a side of the isolation layer away from the first conductive layer, and the second portion is in contact with the first conductive layer.

2. The thin film transistor according to claim 1, further comprising:
a second conductive layer formed on a side of the semiconductor layer away from the first conductive layer, wherein the second conductive layer comprises a first through hole exposing at least a part of the first portion, and the second conductive layer is insulated from the first conductive layer; and
a third conductive layer formed on a side of the first portion of the semiconductor layer away from the isolation layer, wherein the third conductive layer is in contact with the first portion of the semiconductor layer, and the third conductive layer is insulated from the second conductive layer.

3. The thin film transistor according to claim 2, further comprising:
a first insulating layer formed on the side of the semiconductor layer away from the first conductive layer, wherein the first insulating layer comprises a second through hole, and an orthographic projection of the second through hole on the first conductive layer overlaps at least partially with an orthographic projection of the first through hole on the first conductive layer; and
a second insulating layer formed on a side of the first portion away from the first conductive layer, wherein the second insulating layer covers an edge of the first through hole and an edge of the second through hole, the second insulating layer comprises a third through hole exposing a part of the first portion, and the third conductive layer extends at least partially into the third through hole and is in contact with the first portion.

4. The thin film transistor according to claim 2, wherein the first portion comprises a first modified region and a first non-modified region, the first modified region is located on the first surface, a carrier concentration of the first modified region is greater than a carrier concentration of the first non-modified region, and the first modified region is in contact with the third conductive layer.

5. The thin film transistor according to claim 4, wherein the second portion comprises a second modified region in contact with the first conductive layer, and a carrier concentration of the second modified region is greater than the carrier concentration of the first non-modified region.

6. The thin film transistor according to claim 1, further comprising:
a second conductive layer formed on a side of the semiconductor layer away from the first conductive layer, wherein the second conductive layer is insulated from the first conductive layer; and
a fourth conductive layer formed between the first surface of the body portion and the first portion, wherein the fourth conductive layer is in contact with the first portion and the first surface of the body portion.

7. The thin film transistor according to claim 1, wherein the buffer portion surrounds at least a part of the body portion along a circumferential direction of the body portion.

8. A method of manufacturing a thin film transistor, comprising:
forming a first conductive layer;
forming an isolation layer on a side of the first conductive layer, wherein the isolation layer comprises a body portion and a buffer portion that are arranged continuously, the body portion comprises a first surface away from the first conductive layer, the first surface is parallel to the first conductive layer, and a thickness of the buffer portion gradually decreases from a side close to the body portion to a side away from the body portion; and
forming a semiconductor layer, wherein the semiconductor layer comprises a first portion and a second portion that are arranged continuously, the first portion is formed on a side of the isolation layer away from the first conductive layer, and the second portion is in contact with the first conductive layer.

9. The method according to claim 8, further comprising:
forming a second conductive layer on a side of the semiconductor layer away from the first conductive layer, and forming a first through hole in the second conductive layer, wherein the first through hole exposes at least a part of the first portion, and the second conductive layer is insulated from the first conductive layer; and
forming a first modified region and a first non-modified region in the first portion, wherein the first modified region is formed by performing a modification treatment on the part of the first surface exposed by the first through hole, the modification treatment comprises plasma bombardment or ion implantation, and a carrier concentration of the first modified region is greater than a carrier concentration of the first non-modified region.

10. The method according to claim 8, further comprising:
forming a second conductive layer on a side of the semiconductor layer away from the first conductive layer, and forming a first through hole in the second conductive layer, wherein the first through hole exposes at least a part of the first portion, and the second conductive layer is insulated from the first conductive layer; and
forming a second insulating layer on a side of the first portion away from the first conductive layer by magnetron sputtering, wherein the second insulating layer covers an edge of the first through hole, and the second insulating layer comprises a third through hole exposing a part of the first portion.
